(19) United States
(12) Patent Application Publication
(10) Pub. No.: US 2025/0054778 A1
(43) Pub. Date: Feb. 13, 2025

(54) IMPROVED THERMAL AND ELECTRICAL INTERFACE BETWEEN PARTS IN AN ETCH CHAMBER

(71) Applicant: LAM RESEARCH CORPORATION, Fremont, CA (US)

(72) Inventors: Anthony DE LA LLERA, Fremont, CA (US); Pratik MANKIDY, Fremont, CA (US); John HOLLAND, San Jose, CA (US)

(21) Appl. No.: 18/719,047

(22) PCT Filed: Dec. 8, 2022
(86) PCT No.: PCT/US2022/052263

§ 371 Date: Jun. 12, 2024

Related U.S. Application Data
(60) Provisional application No. 63/290,007, filed on Dec. 15, 2021.

(51) Int. Cl. H01L 21/67; H01J 37/32; H01L 21/687

(52) U.S. Cl. CPC H01L 21/67017; H01J 37/32642; H01J 37/32724; H01L 21/67109; H01L 21/68735; H01L 21/68757; H01L 21/68785; H01J 2237/002; H01J 2237/2007; H01J 2237/334

(57) ABSTRACT

An assembly for a processing chamber of a substrate processing system includes a first component, a second component, and a thermal interface material arranged between the first component and the second component. At least one of the first component and the second component is configured to be exposed to plasma within the processing chamber, the thermal interface material has a first surface that faces and is in direct contact with the first component and a second surface that faces and is in direct contact with the second component the thermal interface material is comprised of a silicon polymer with at least one of aligned carbon fibers and carbon nanotubes (CNTs), wherein the at least one of the carbon fibers and the CNTs are aligned in a direction perpendicular to the first surface and the second surface.

### CROSS-REFERENCE TO RELATED APPLICATIONS

This application claims the benefit of U.S. Provisional Application No. 63/290,007, filed on Dec. 15, 2021. The entire disclosure of the application referenced above is incorporated herein by reference.

### FIELD

The present disclosure relates to controlling thermal and electrical conductivity between components in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, dielectric etch, and/or other etch, deposition, or cleaning processes. A substrate may be arranged on a substrate support, such as a pedestal, an electrostatic chuck (ESC), etc. in a processing chamber of the substrate processing system. During etching, etch gas mixtures including one or more gases may be introduced into the processing chamber and plasma may be used to initiate chemical reactions.

The substrate support may include a ceramic layer arranged to support a substrate. For example, the substrate may be clamped to the ceramic layer during processing. The substrate support may include an edge ring arranged to surround an outer perimeter of the ceramic layer and the substrate.

The processing chamber may include an upper electrode and a lower electrode. The substrate support (e.g., a baseplate of the substrate support) may be configured to function as the lower electrode. In some examples, gas mixtures are introduced into the processing chamber using a gas distribution device such as a showerhead. The gas distribution device may be configured to function as the upper electrode.

### SUMMARY

An assembly for a processing chamber of a substrate processing system includes a first component, a second component, and a thermal interface material arranged between the first component and the second component. At least one of the first component and the second component is configured to be exposed to plasma within the processing chamber, the thermal interface material has a first surface that faces and is in direct contact with the first component and a second surface that faces and is in direct contact with the second component, the thermal interface material is comprised of a silicon polymer with at least one of aligned carbon fibers and carbon nanotubes (CNTs), wherein the at least one of the carbon fibers and the CNTs are aligned in a direction perpendicular to the first surface and the second surface.

In other features, the assembly is an upper electrode. The first component is a backplate of the upper electrode and the second component is a faceplate of the upper electrode. The thermal interface material is configured as a thermal interface gasket arranged between the backplate and the faceplate. The thermal interface gasket includes a plurality of segments. The thermal interface gasket includes a plurality of openings aligned with corresponding openings defined in at least one of the backplate and the faceplate, and borders between the plurality of segments do not intersect any of the plurality of openings. The plurality of segments includes a central segment surrounded by a plurality of outer segments. At least one of the plurality of segments has a different thermal conductivity than others of the plurality of segments. The thermal interface gasket includes a plurality of alignment holes configured to receive respective ones of a plurality of alignment pins extending from at least one of the backplate and the faceplate.

In other features, the assembly is a substrate support. The first component is a baseplate of the substrate support and the second component is an edge ring. The thermal interface material is configured as a thermal interface ring arranged between the baseplate and the edge ring. The thermal interface ring includes a plurality of segments. The plurality of segments includes a plurality of arcs of the thermal interface ring. At least one of the plurality of segments has a different thermal conductivity than others of the plurality of segments. The thermal interface ring includes a plurality of alignment holes configured to receive respective ones of a plurality of alignment pins extending from at least one of the baseplate and the edge ring. The assembly further includes a second thermal interface ring arranged radially outside of the thermal interface ring. Thermal conductivities of the thermal interface ring and the second thermal interface ring are different. The assembly further includes an adhesive between the thermal interface material and at least one of the first component and the second component. The adhesive includes a thermally-conductive epoxy.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example substrate processing system according to the present disclosure;

FIG. 2A is an example upper electrode including a thermal interface gasket according to the present disclosure;

FIG. 2B is a plan view of an example thermal interface gasket according to the present disclosure;

FIG. 3A is an example substrate support including a thermal interface ring according to the present disclosure;

FIG. 3B is a plan view of the example thermal interface ring of FIG. 3A according to the present disclosure; and

FIG. 3C is another example substrate support including a thermal interface ring according to the present disclosure.

In the drawings, reference numbers may be reused to identify similar and/or identical elements.

### DETAILED DESCRIPTION

In a substrate processing chamber, temperatures of components such as an edge ring, an upper electrode, etc. affect processing parameters such as etch rate and uniformity at an outer edge of a substrate. For example, edge rings and upper electrodes are exposed to the processing environment (including plasma) and absorb heat. Accordingly, respective temperatures of these components vary during processing and controlling the temperatures helps achieve repeatable process performance (e.g., etch rates) and uniformity.

In some examples, a gas distribution device such as a showerhead is configured to function as the upper electrode. For example, the upper electrode includes two or more plates (e.g., a faceplate, a backplate, etc.) with holes for flowing gas mixtures into a processing volume of the processing chamber. A thermal interface material such as a silicone-based gel, paste, pad, etc. may be arranged between the plates to facilitate heat transfer from the faceplate to the backplate. For example, the backplate may be temperature-controlled (e.g., cooled) and functions as a heat sink for the faceplate.

Conversely, the edge ring is arranged in thermal contact with a baseplate or lower ring of the substrate support. For example, the baseplate may function as a heat sink for the edge ring and heat is transferred via an interface between the edge ring and the baseplate. The thermal interface material may be provided between the edge ring and the baseplate to facilitate transfer of heat from the edge ring to the baseplate. The baseplate may include coolant channels configured to flow coolant and transfer heat out of the baseplate.

The thermal interface material (e.g., a silicone gel or paste or a silicon rubber pad) is difficult to install, may not have consistent properties in every processing chamber, and/or the properties of the thermal interface material may change over time, contributing to component temperature drift. For example, the thermal interface material may be exposed to process materials (e.g., plasma), further degrading the heat transfer characteristics. Replacing and servicing the edge ring or components of the upper electrode require extensive cleaning (e.g., of the substrate support) to remove the thermal interface material.

Further, temperatures of the upper electrode, the edge ring, and other components will vary in accordance with radio frequency (RF) power delivered to the processing chamber, thermal conductivity of the interface and/or interface material, contact area, etc. As process power increases due to system performance and product requirements, chamber components are exposed to increased temperatures. Heat transfer characteristics and reliability of current thermal interface materials may not be sufficient at greater temperatures associated with increased RF power. Consequently, components may overheat, leading to reduced reliability and lifetime.

Systems and methods according to the present disclosure implement a thermal interface material with improved heat transfer characteristics and reliability, mechanical coupling, and temperature uniformity relative to silicone-based gels and pastes or silicon rubber pads. The thermal interface material also provides increased electrical conductivity and improves ease of installation and replacement. The thermal interface material of the present disclosure comprises a polymer composite, carbon fiber sheet. More specifically, the thermal interface material comprises a silicon polymer with aligned carbon fibers and/or nanotubes.

Although described herein with respect to the upper electrode and edge ring, the thermal interface material of the present disclosure may be arranged between other components in respective assemblies in a substrate processing system (e.g., between adjacent layers of a substrate support, between different components in an edge ring system comprised of multiple rings, such as a bottom ring, middle ring, and top ring, etc.).

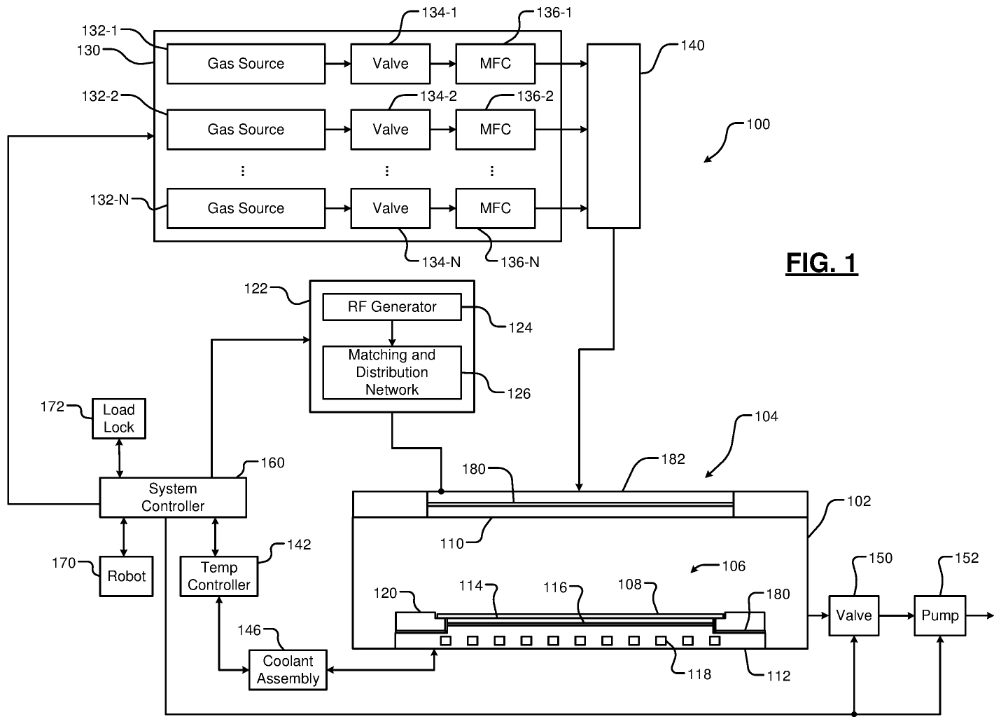

Referring now to FIG. 1, an example substrate processing system 100 is shown. For example only, the substrate processing system 100 may be used for performing etching using RF plasma and/or other suitable substrate processing. The substrate processing system 100 includes a processing chamber 102 that encloses other components of the substrate processing system 100 and contains the RF plasma. The substrate processing chamber 102 includes an upper electrode 104 and a substrate support 106, such as an ESC. During operation, a substrate 108 is arranged on the substrate support 106. While a specific substrate processing system 100 and processing chamber 102 are shown as an example, the principles of the present disclosure may be applied to other types of substrate processing systems and processing chambers, such as a substrate processing system that generates plasma in-situ, that implements remote plasma generation and delivery (e.g., using a plasma tube, a microwave tube), etc.

For example only, the upper electrode 104 may be implemented as a gas distribution device, such as a showerhead, that introduces and distributes process gases. A substrate-facing surface or faceplate 110 of the upper electrode 104 includes a plurality of holes through which process gas or purge gas flows. In other examples, the upper electrode 104 may include a conducting plate and the process gases may be introduced in another manner.

The substrate support 106 includes a conductive baseplate 112 that functions as a lower electrode. The baseplate 112 supports a ceramic layer 114. A bond layer (e.g., an adhesive and/or thermal bond layer) 116 may be arranged between the ceramic layer 114 and the baseplate 112. The baseplate 112 may include one or more coolant channels 118 for flowing coolant through the baseplate 112. The substrate support 106 may include an edge ring 120 arranged to surround an outer perimeter of the substrate 108. In some examples, the edge ring 120 may be actively heated.

An RF generating system 122 generates and outputs an RF voltage to one of the upper electrode 104 and the lower electrode (e.g., the baseplate 112 of the substrate support 106). The other one of the upper electrode 104 and the baseplate 112 may be DC grounded, AC grounded or floating. In the present example, the RF voltage is supplied to the upper electrode. For example only, the RF generating system 122 may include an RF voltage generator 124 that generates the RF voltage that is fed by a matching and distribution network 126 to the upper electrode 104 or the baseplate 112. In other examples, the plasma may be generated inductively or remotely. Although, as shown for example purposes, the RF generating system 122 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more etch gases and mixtures thereof. The gas sources may also supply carrier and/or purge gas. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 110.

A temperature controller 142 may communicate with a coolant assembly 146 to control coolant flow through the channels 118. For example, the coolant assembly 146 may include a coolant pump and reservoir. The temperature controller 142 operates the coolant assembly 146 to selectively flow the coolant through the channels 118 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160.

A thermal interface material according to the principles of the present disclosure is arranged between various adjacent components of the processing chamber 102. For example, a thermal interface gasket 180 comprising the thermal interface material is provided between the faceplate 110 and a backplate 182 of the upper electrode 104. The thermal interface gasket 180 facilitates cooling of the upper electrode 104 (i.e., heat transfer from the faceplate 110 to the backplate 182). Similarly, a thermal interface sheet or ring 184 comprising the thermal interface material is provided between the edge ring 120 and the baseplate 112. The thermal interface ring 184 facilitates cooling of the edge ring 120 (i.e., heat transfer from the edge ring 120 to the baseplate 112).

The thermal interface material of the thermal interface gasket 180 and the thermal interface ring 184 comprises a polymer composite, carbon fiber sheet (e.g., a silicon polymer with aligned carbon fibers and/or nanotubes) as described below in more detail.

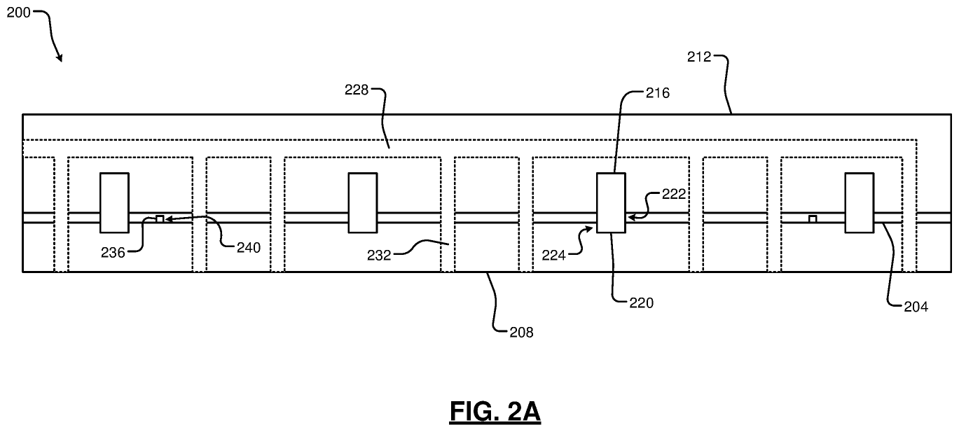

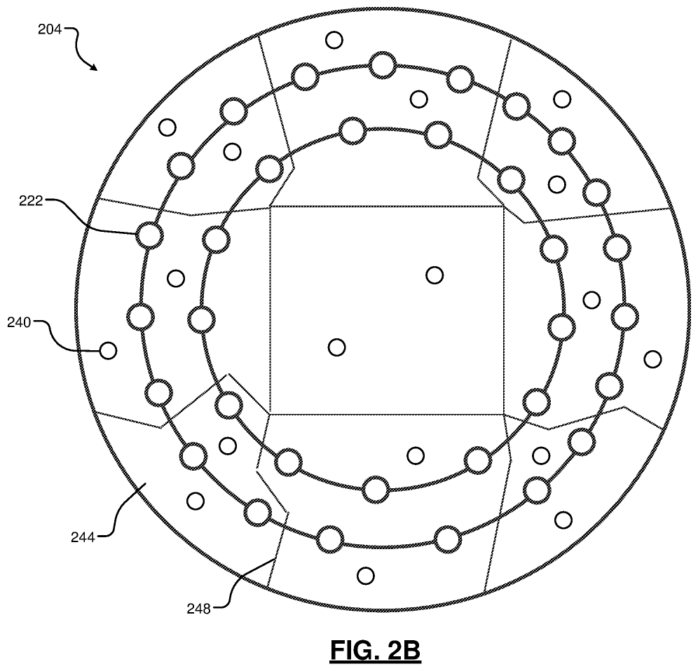

Referring now to FIGS. 2A and 2B, a cross-section of an example assembly including two or more adjacent components (e.g., an upper electrode 200 including a thermal interface gasket 204 according to the present disclosure) and a plan view of the thermal gasket 204, respectively, are shown. The upper electrode 200 includes a plasma-facing faceplate 208 and a backplate 212. In some examples, the backplate 212 is temperature-controlled. For example, the backplate 212 may be actively cooled using a cooling gas or liquid and functions as a heat sink for the faceplate 208. In other words, as plasma processing causes a temperature of the faceplate 208 to increase, the upper electrode 200 is configured to transfer heat from the faceplate 208 to the backplate 212 to cool the faceplate 208.

The thermal interface gasket 204 is arranged between the faceplate 208 and the backplate 212. For example, a first (e.g., upper) surface of the thermal interface gasket 204 faces and is in direct contact with the backplate 212. A second (e.g., lower) surface of the thermal interface gasket 204 faces and is in direct contact with the faceplate 208. The thermal interface gasket 204 is configured to facilitate heat transfer and electrical conductivity between the faceplate 208 and the backplate 212. For example, the thermal interface gasket 204 comprises a material having a thermal conductivity from 16-35 Watts per meter Kelvin (W/m-K). The thermal interface gasket 204 comprises a polymer composite, carbon fiber sheet, such as a silicon polymer sheet with aligned carbon fibers and/or nanotubes. In some examples, the thermal interface gasket 204 has a thickness between 0.1 mm and 3.0 mm. In one example, the thermal interface gasket 204 is 0.2 mm to 0.3 mm thick.

In some examples, the faceplate 208 is attached to the backplate 212 using a plurality of fasteners, such as pull-down rods or clamps 216. For example, each of the clamps 216 may include a threaded lower end 220 that extends from the backplate 212, through openings 222 in the thermal interface gasket 204, and into a respective opening 224 in an upper surface of the faceplate. Similarly, in examples where the upper electrode 200 is configured to function as a gas distribution device or showerhead, process gases are supplied to the processing chamber 102 from a manifold or plenum 228 defined in the backplate into channels 232 that pass through the openings 222 in the thermal interface gasket 204. The channels 232 pass through the faceplate 208 to allow process gases to flow into the processing chamber 102.

In some examples, one or more alignment features (e.g., alignment pins 236, as shown) extend upward from the faceplate 208 and/or downward from the backplate 212 into complementary alignment features (e.g., alignment holes 240) defined in the thermal interface gasket 204. The alignment pins 236 are inserted into the alignment holes 240 to position (e.g., center) the thermal interface gasket 204 on the faceplate 208.

As shown in a plan (i.e., top-down) view in FIG. 2B, in one example the thermal interface gasket 204 is comprised of a plurality of interlocking segments 244. For example, as shown, the thermal interface gasket 204 includes nine of the segments 244 (e.g., one central segment surrounded by eight outer segments). Although shown as generally square-shaped, the central segment may have any suitable shape. In some examples, the eight outer segments may be a same size and shape. In other examples (as shown), the outer segments are irregularly shaped. For example, borders 248 between the segments 244 may be configured such that each of the openings 222 are defined entirely within respective segments 244. As shown, the borders 248 weave between and around the openings 222 in a piecewise linear manner. In other words, none of the openings 222 overlaps more than one of the segments 244 and the borders 240 do not intersect any of the openings 222. Similarly, each of the segments 244 may include one or more of the alignment holes 240. In other examples, the borders 248 may be curvilinear. The alignment holes 240 for respective segments 244 may be a same size or different sizes.

In other examples, the thermal interface gasket 204 is comprised of a single, integral piece instead of the plurality of segments 244. In other examples, the segments 244 may be configured as a plurality of different azimuthal or radial zones and one or more of the segments 244 may comprise a different thermal interface material than others of the segments 244. In this manner, different segments of the thermal interface gasket 204 may provide different heat transfer characteristics to different regions of the upper electrode 200.

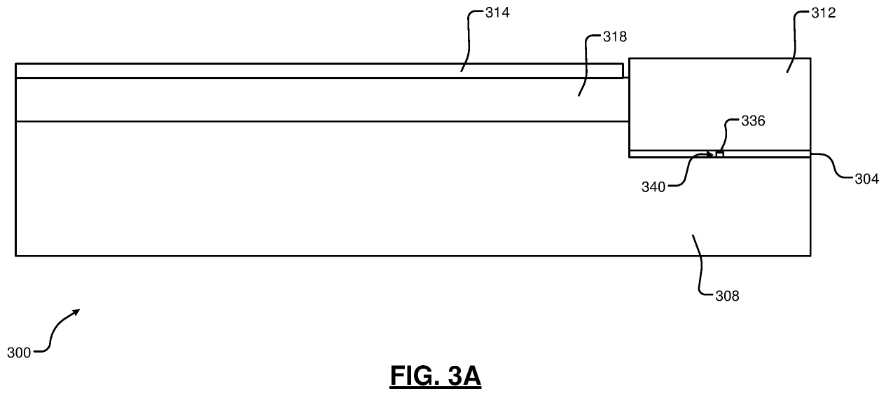

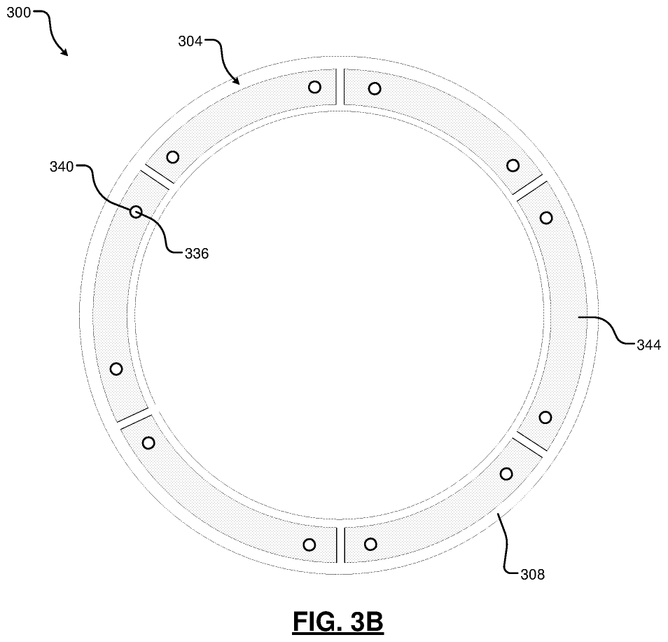

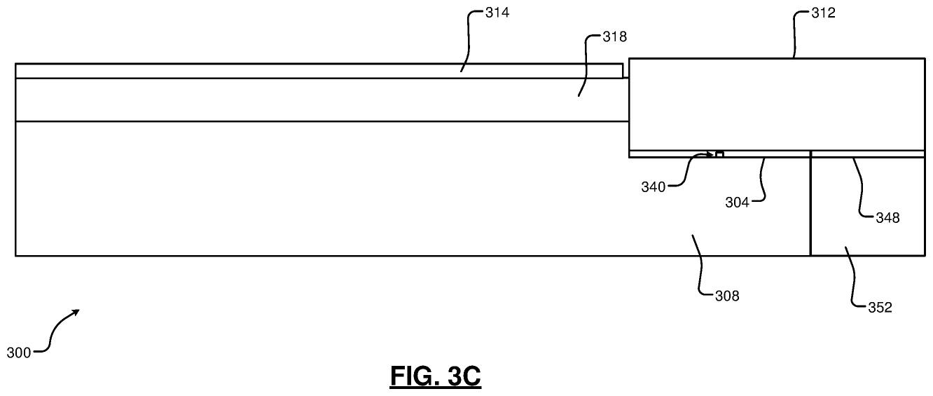

Referring now to FIGS. 3A and 3B, a cross-section of another example assembly including two or more adjacent components (e.g., a substrate support 300 including a thermal interface ring 304 according to the present disclosure) and a plan view of the thermal interface ring 304 arranged on the substrate support 300, respectively, are shown. The substrate support 300 includes a baseplate (e.g., a conductive aluminum baseplate 308 that functions as a lower electrode) and an edge ring 312. In some examples, the edge ring 312 is temperature-controlled. For example, the edge ring 312 may be actively heated to adjust process performance at an edge of a substrate 314. In some examples, the edge ring 312 is heated using resistive heating. A ceramic layer 318 may be arranged on the baseplate 308 and the substrate 314 is arranged on the ceramic layer 318.

Conversely, the baseplate 308 may be cooled using a cooling gas or liquid and functions as a heat sink for the edge ring 312. In other words, a temperature of the edge ring 312 increases, the baseplate 308 is configured to transfer heat from the edge ring 312 to cool the edge ring. The thermal interface ring 304 is arranged between the baseplate 308 and the edge ring 312 to facilitate heat transfer and electrical conductivity between the edge ring 312 and the baseplate 308. For example, the thermal interface ring 304 comprises a material having a thermal conductivity from 16-35 Watts per meter Kelvin (W/m-K). A first (e.g., upper) surface of the thermal interface ring 304 faces and is in direct contact with the edge ring 312. A second (e.g., lower) surface of the thermal interface ring 304 faces and is in direct contact with the baseplate 208. The thermal interface ring 304 comprises a polymer composite, carbon fiber sheet, such as a silicon polymer sheet with aligned carbon fibers and/or nanotubes. In some examples, the thermal interface ring 304 has a thickness between 0.1 mm and 3.0 mm. In one example, the thermal interface ring 304 is 0.2 mm to 0.3 mm thick.

In some examples, one or more alignment features (e.g., alignment pins 336, as shown) extend upward from the baseplate 308 into complementary alignment features (e.g., alignment holes 340) defined in the thermal interface ring 304. The alignment pins 336 are inserted into the alignment holes 340 to position (e.g., center) the thermal interface ring 304 on the baseplate 308.

As shown in a plan (i.e., top-down) view in FIG. 3B, in one example the thermal interface ring 304 is comprised of a plurality of segments 344. For example, as shown, the thermal interface ring 304 includes six of the segments 344 (e.g., six arcs, or arcuate segments, of the annular thermal interface ring 304). In some examples, the segments 344 may be a same size and shape. In other examples (as shown), the segments 344 are not the same size. Each of the segments 344 may include one or more of the alignment holes 340. The alignment holes 340 for respective segments 344 may be a same size or different sizes.

In other examples, the thermal interface ring 304 is comprised of a single, integral annular piece instead of the plurality of segments 344. In other examples, the segments 344 may be configured as a plurality of different azimuthal or radial zones and one or more of the segments 344 may comprise a different thermal interface material than others of the segments 344. In this manner, different segments of the thermal interface ring 304 may provide different heat transfer characteristics to different regions of the edge ring 312.

In another example shown in FIG. 3C, a second thermal interface ring 348 is provided between an outer perimeter of the edge ring 312 and the substrate support 300. For example, the substrate support 300 includes a bottom ring (e.g., an insulator ring) 352 around the baseplate 308 and the outer perimeter of the edge ring 312 is supported on the bottom ring 352. The second thermal interface ring 348 may comprise a same material as the thermal interface ring 304 or a different material. For example, the second thermal interface ring 348 may be comprise a silicone-based gel, paste, pad, etc. In this manner, the thermal interface ring 304 and the second thermal interface ring 348 may have same or different heat transfer characteristics.

The thermal interface material of the thermal interface gasket 204 and the thermal interface ring 304 comprises a composite of a polymer (e.g., a silicon polymer) and aligned carbon fibers and/or carbon nanotubes (CNTs). For example, the CNTs are aligned within a polymer matrix. The aligned configuration of the CNTs forms thermally and electrically conductive paths through the thermal interface material. For example, the CNTs are aligned in a direction perpendicular to surfaces of the thermal interface material to provide thermal and electrical conductivity in a direction normal to the surfaces of the thermal interface material.

In any of the examples above, an adhesive may be provided between surfaces of the thermal interface material (e.g. surfaces of the thermal interface ring 304) and adjacent surfaces of the edge ring 312, the baseplate 308, and/or the bottom ring 352. The adhesive may be provided on an upper surface, a lower surface, or both an upper and lower surface of the thermal interface ring 304. The adhesive may comprise a thermal adhesive, such as a thermally-conductive epoxy. The adhesive may be applied as a layer, as dots or another discontinuous pattern, etc. The adhesive may be provided instead of or in addition to the alignment holes 340. In this manner, the adhesive facilitates retention of a desired position of the thermal interface ring 304.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An assembly for a processing chamber of a substrate processing system, the assembly comprising:
a first component;
a second component, wherein at least one of the first component and the second component is configured to be exposed to plasma within the processing chamber; and
a thermal interface material arranged between the first component and the second component, wherein the thermal interface material has a first surface that faces and is in direct contact with the first component and a second surface that faces and is in direct contact with the second component, wherein the thermal interface material is comprised of a silicon polymer with at least one of aligned carbon fibers and carbon nanotubes (CNTs), wherein the at least one of the carbon fibers and the CNTs are aligned in a direction perpendicular to the first surface and the second surface.

2. The assembly of claim 1, wherein the assembly is an upper electrode.

3. The assembly of claim 2, wherein the first component is a backplate of the upper electrode and the second component is a faceplate of the upper electrode.

4. The assembly of claim 3, wherein the thermal interface material is configured as a thermal interface gasket arranged between the backplate and the faceplate.

5. The assembly of claim 4, wherein the thermal interface gasket comprises a plurality of segments.

6. The assembly of claim 5, wherein the thermal interface gasket comprises a plurality of openings aligned with corresponding openings defined in at least one of the backplate and the faceplate, and wherein borders between the plurality of segments do not intersect any of the plurality of openings.

7. The assembly of claim 5, wherein the plurality of segments includes a central segment surrounded by a plurality of outer segments.

8. The assembly of claim 5, wherein at least one of the plurality of segments has a different thermal conductivity than others of the plurality of segments.

9. The assembly of claim 4, wherein the thermal interface gasket comprises a plurality of alignment holes configured to receive respective ones of a plurality of alignment pins extending from at least one of the backplate and the faceplate.

10. The assembly of claim 1, wherein the assembly is a substrate support.

11. The assembly of claim 10, wherein the first component is a baseplate of the substrate support and the second component is an edge ring.

12. The assembly of claim 11, wherein the thermal interface material is configured as a thermal interface ring arranged between the baseplate and the edge ring.

13. The assembly of claim 12, wherein the thermal interface ring comprises a plurality of segments.

14. The assembly of claim 13, wherein the plurality of segments includes plurality of arcs of the thermal interface ring.

15. The assembly of claim 13, wherein at least one of the plurality of segments has a different thermal conductivity than others of the plurality of segments.

16. The assembly of claim 12, wherein the thermal interface ring comprises a plurality of alignment holes configured to receive respective ones of a plurality of alignment pins extending from at least one of the baseplate and the edge ring.

17. The assembly of claim 12, further comprising a second thermal interface ring arranged radially outside of the thermal interface ring.

18. The assembly of claim 17, wherein thermal conductivities of the thermal interface ring and the second thermal interface ring are different.

19. The assembly of claim 1, further comprising an adhesive between the thermal interface material and at least one of the first component and the second component.

20. The assembly of claim 19, wherein the adhesive comprises a thermally-conductive epoxy.
